(19) United States
(12) Patent Application Publication
(10) Pub. No.: US 2020/0243745 A1
(43) Pub. Date: Jul. 30, 2020

(54) MULTILAYER PIEZOELECTRIC ELEMENT

(71) Applicant: TDK CORPORATION, Tokyo (JP)

(72) Inventors: Makoto ISHIZAKI, Tokyo (JP); Masaharu HIRAKAWA, Tokyo (JP)

(73) Assignee: TDK CORPORATION, Tokyo (JP)

(21) Appl. No.: 16/776,754

(22) Filed: Jan. 30, 2020

(30) Foreign Application Priority Data
Jan. 30, 2019 (JP) 2019-014465

(51) Int. Cl. H01L 41/047; H01L 41/083

(52) U.S. Cl. CPC H01L 41/0471; H01L 41/083

(57) ABSTRACT

A multilayer piezoelectric element includes a laminated body and a lateral electrode. The laminated body includes a piezoelectric layer, an internal electrode layer, and a dummy electrode layer. The piezoelectric layer is formed along a plane including a first axis and a second axis perpendicular to each other. The internal electrode layer and the dummy electrode layer are laminated on the piezoelectric layer. The lateral electrode is formed on a lateral surface of the laminated body perpendicular to the first axis. The internal electrode layer has a leading portion exposed to the lateral surface of the laminated body and is electrically connected with the lateral electrode via the leading portion. The dummy electrode layer is formed on the plane to surround the internal electrode layer excluding the leading portion with a gap therebetween. A slit is formed at least at one or more positions of the dummy electrode layer.

### BACKGROUND OF THE INVENTION

The present invention relates to a multilayer piezoelectric element and to a piezoelectric actuator utilizing it.

Multilayer piezoelectric elements have a structure in which internal electrodes and piezoelectric layers are laminated and can increase displacement amount and driving force per unit volume compared to non-multilayer piezoelectric elements. To prevent short circuit by migration between internal electrode layers, it is normal for the multilayer piezoelectric elements that a lamination area of the internal electrode layers is smaller than that of the piezoelectric layers. In such a multilayer structure, however, generated is a shrinkage difference between a portion on which the internal electrode layers are present and a portion on which the internal electrode layers are absent, and the laminated body may deform or have cracks.

To prevent such a problem, Patent Document 1 discloses a technique of preventing generation of cracks in a piezoelectric layer during manufacture by forming a dummy electrode on an outer circumference of an internal electrode layer. However, the present inventors have found that the technique of Patent Document 1 cannot sufficiently prevent deformation of the laminated body when the piezoelectric layer is thin, when the number of piezoelectric layers is large, or when the element body is large.
Patent Document 1: JP3794292 (B2)

### BRIEF SUMMARY OF INVENTION

The present invention has been achieved under such circumstances. It is an object of the invention to provide a multilayer piezoelectric element having an improved flatness by prevention of deformation of an element body.

To achieve the above object, a multilayer piezoelectric element according to the present invention includes:

a laminated body including:
a piezoelectric layer formed along a plane including a first axis and a second axis perpendicular to each other; and
an internal electrode layer and a dummy electrode layer laminated on the piezoelectric layer, and

a lateral electrode formed on a lateral surface of the laminated body perpendicular to the first axis,

wherein the internal electrode layer has a leading portion exposed to the lateral surface of the laminated body and is electrically connected with the lateral electrode via the leading portion,

wherein the dummy electrode layer is formed on the plane to surround the internal electrode layer excluding the leading portion with a gap therebetween, and

wherein a slit is formed at least at one or more positions of the dummy electrode layer.

In the multilayer piezoelectric element according to the present invention, the dummy electrode layer is formed around the internal electrode layer, and the slit is formed on the dummy electrode layer. The present inventors have found that the present invention makes it possible to prevent deformation of the laminated body in a firing step even if the element body is thin and large and to obtain a multilayer piezoelectric element with an improved flatness after firing.

Incidentally, the appearance of deformation prevention effect is caused by the following reason. The laminated body (element body) of the multilayer piezoelectric element is obtained by laminating ceramic green sheets (ceramic layers) to be piezoelectric layers and conductive pastes (electrode layers) to be electrode patterns and firing them. In the firing step, each layer has volume shrinkage, but the heat shrinkage behaviors are different from each other between the ceramic layers and the electrode layers.

In general, the shrinkage factor of the electrode layers is larger than that of the ceramic layers. Thus, shrinkage stress occurs near the electrode layers, and tensile stress occurs near the ceramic layers. The stress generated inside the laminated body is considered to deform the laminated body. In the present invention, the slit is formed on the dummy electrode layer, and the stress can be released by the slit. Thus, the multilayer piezoelectric element according to the present invention is hard to be affected by thermal shrinkage in the firing step and can prevent deformation of the laminated body after firing.

Since the slit is formed on the dummy electrode layer, the multilayer piezoelectric element according to the present invention can increase an area ratio of the internal electrode layer even while ensuring a favorable flatness. Specifically, a ratio of an area (Ae) of the internal electrode layer to an area (Ap) of the piezoelectric layer in the plane can be 0.95≤Ae/Ap≤0.99. The area of the internal electrode layer corresponds to an area of a piezoelectric active part, which demonstrates piezoelectric characteristics. Thus, when the internal electrode layer has a high area ratio, the relative dielectric constant ε and the piezoelectric constant d33 (or d31) of the piezoelectric element can be improved.

Preferably, the slit is formed on the dummy electrode layer at a position away from an end of the dummy electrode layer near the leading portion by a predetermined distance or more. Preferably, the predetermined distance is ⅛ or more (more preferably, ⅙ or more) of a first-axis width of the dummy electrode layer in the first axis.

When the slit is formed at such a position, the multilayer piezoelectric element according to the present invention can more effectively reduce the stress generated in the dummy electrode layer and can have a high improvement effect on flatness.

The dummy electrode layer may include two lateral patterns along the first axis and a joint pattern along the second axis. The joint pattern may be positioned opposite to the leading portion and joints the lateral patterns. Preferably, the slit is formed at a center of the joint pattern or the lateral patterns of the dummy electrode layer.

The shrinkage stress generated in the electrode layer in the firing is considered to easily concentrate on a central part of the outer circumference of the electrode pattern. In the present invention, the stress can more effectively be released by forming the slit at a central part of each pattern, on which the stress is easy to concentrate. It is thereby possible to prevent swell and dent of the laminated body at a central position of each electrode pattern and to more effectively prevent deformation of the laminated body.

Preferably, two or more slits are formed line-symmetrically to a center line equally dividing the dummy electrode layer and being parallel to the first axis. When the slits are formed regularly in such a manner, the present invention makes it possible to prevent the stress from partially concentrating on the dummy electrode layer and to enhance deformation prevention effect of the laminated body.

Preferably, the slit has a width of 0.03 to 0.6 mm. In this range, the slit is easily formed, and the function of the dummy electrode layer can sufficiently be secured.

Preferably, a corner of the internal electrode layer is rounded with a curvature radius of 0.1 mm or larger.

An electric field is easy to concentrate on the corner of the internal electrode layer at the time of application of DC electric field during polarization. In particular, when the piezoelectric layer is made of a lead-free based material, a rated voltage for polarization is high, and short circuit is easily generated at the corner of the internal electrode layer during polarization. In the present invention, when the corner of the internal electrode layer is rounded, an electric field is prevented from concentrating on the corner, and short-circuit failure can effectively be prevented from occurring during polarization.

The multilayer piezoelectric element according to the present invention can be utilized as a conversion element from electrical energy to mechanical energy. For example, the multilayer piezoelectric element according to the present invention is applicable to piezoelectric actuators, piezoelectric buzzers, piezoelectric sounders, ultrasonic motors, speakers, etc. and is particularly favorably utilized as piezoelectric actuators. Specifically, the piezoelectric actuators are utilized for haptic devices, lens driving, HDD head driving, inkjet printer head driving, fuel injection valve driving, etc.

### BRIEF DESCRIPTION OF DRAWINGS

FIG. 1 is a schematic perspective view illustrating a multilayer piezoelectric element according to an embodiment of the present invention.

FIG. 2 is a schematic cross-sectional view cut along the II-II line shown in FIG. 1.

FIG. 3 is a schematic cross-sectional view cut along the III-III line shown in

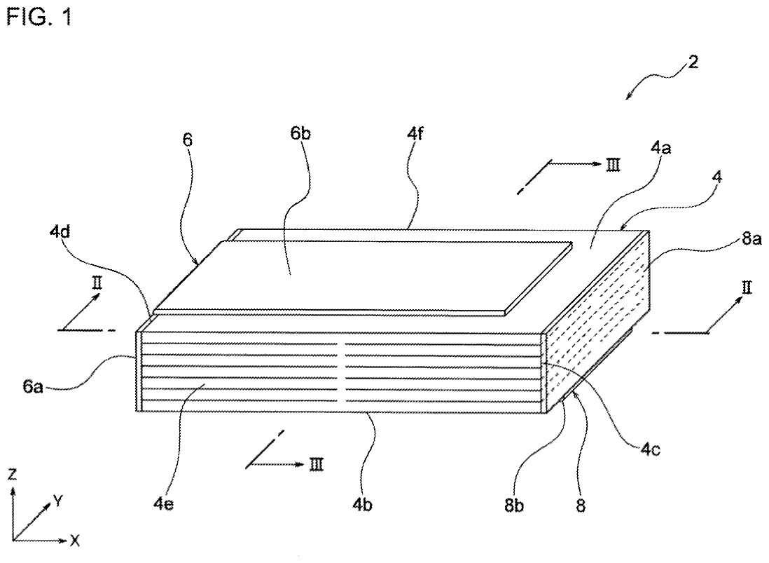

FIG. 1.

FIG. 4A is a plane view illustrating a first electrode pattern contained in the multilayer piezoelectric element shown in FIG. 1.

FIG. 4B is a plane view illustrating a second electrode pattern contained in the multilayer piezoelectric element shown in FIG. 1.

FIG. 5 is an exploded perspective view of the multilayer piezoelectric element shown in FIG. 1.

FIG. 6 is a plane view illustrating an electrode pattern contained in a multilayer piezoelectric element according to another embodiment.

FIG. 7A is a plane view illustrating an electrode pattern contained in a multilayer piezoelectric element according to another embodiment.

FIG. 7B is a plane view illustrating an electrode pattern contained in a multilayer piezoelectric element according to another embodiment.

### DETAILED DESCRIPTION OF INVENTION

Hereinafter, the present invention is explained based on embodiments shown in the figures.

### First Embodiment

FIG. 1 is a schematic perspective view of a multilayer piezoelectric element 2 according to the present embodiment. As shown in FIG. 1, the multilayer piezoelectric element 2 includes a laminated body 4, a first external electrode 6, and a second external electrode 8.

The laminated body 4 has a substantially rectangular parallelepiped shape and has a front surface 4a and a back surface 4b substantially perpendicular to the Z-axis direction, lateral surfaces 4c and 4d substantially perpendicular to the X-axis (first axis) direction, and lateral surfaces 4e and 4f substantially perpendicular to the Y-axis (second axis) direction. Incidentally, insulating protect layers (not illustrated) may be formed on the lateral surfaces 4e and 4f of the laminated body 4. In the figures, the X-axis, the Y-axis, and the Z-axis are substantially perpendicular to each other.

The first external electrode 6 has a first lateral part 6a formed along the lateral surface 4d of the laminated body 4 and a first surface part 6b formed along the front surface 4a of the laminated body 4. The first lateral part 6a and the first surface part 6b have a substantially rectangular shape and are connected with each other at their intersection. Incidentally, the first lateral part 6a and the first surface part 6b are illustrated separately in the figures, but are actually formed integrally.

The second external electrode 8 has a second lateral part 8a formed along the lateral surface 4c of the laminated body 4 and a second surface part 8b formed along the back surface 4b of the laminated body 4. As with the first external electrode 6, the second lateral part 8a and the second surface part 8b have a substantially rectangular shape and are connected with each other to be formed integrally at their intersection. As shown in FIG. 1, the first surface part 6b and the second surface part 8b are smaller than a plane of the laminated body 4 perpendicular to the Z-axis direction (the front surface 4a or the back surface 4b of the laminated body 4), and the first external electrode 6 and the second external electrode 8 are insulated with each other.

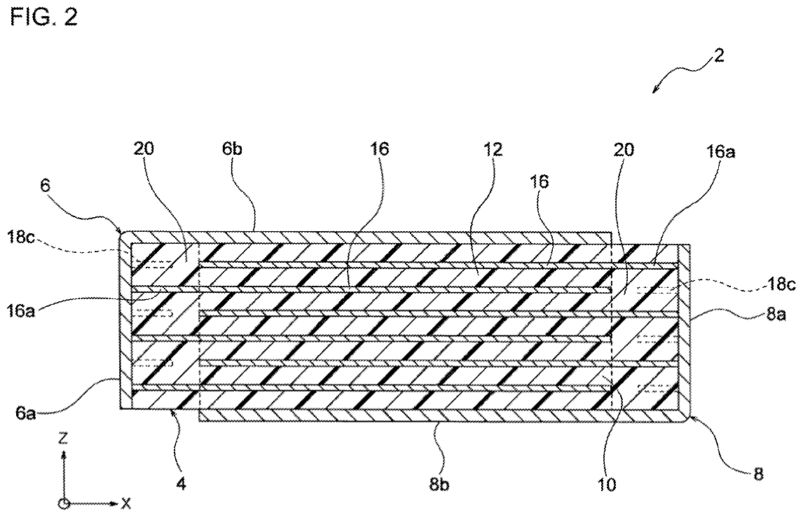

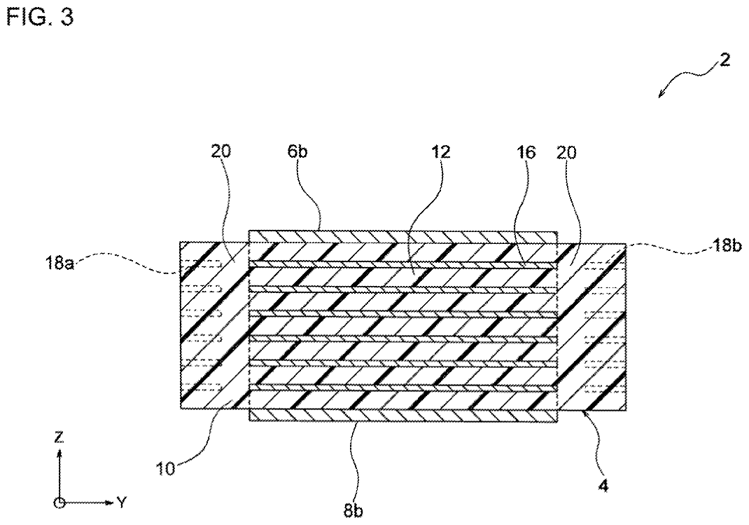

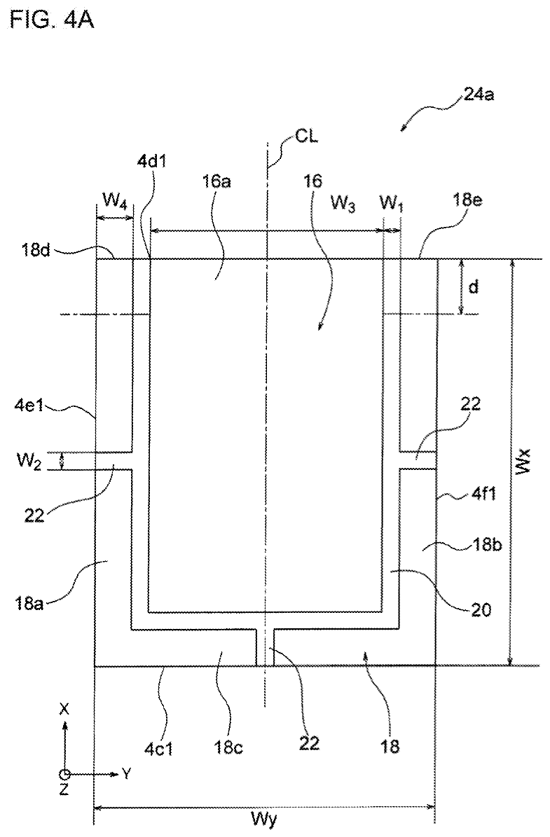

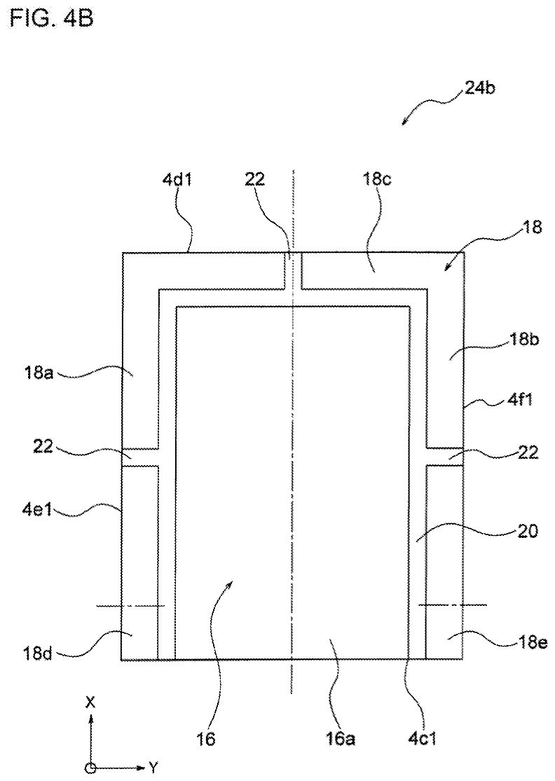

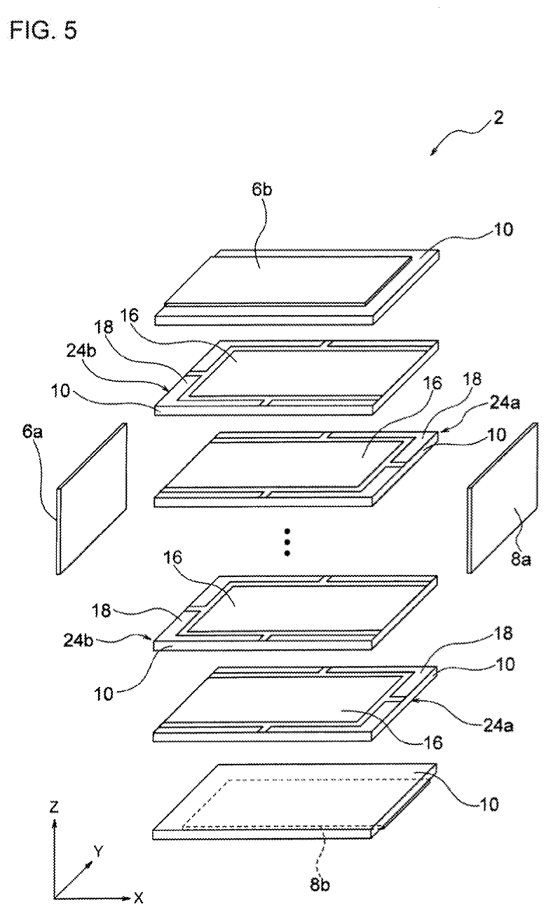

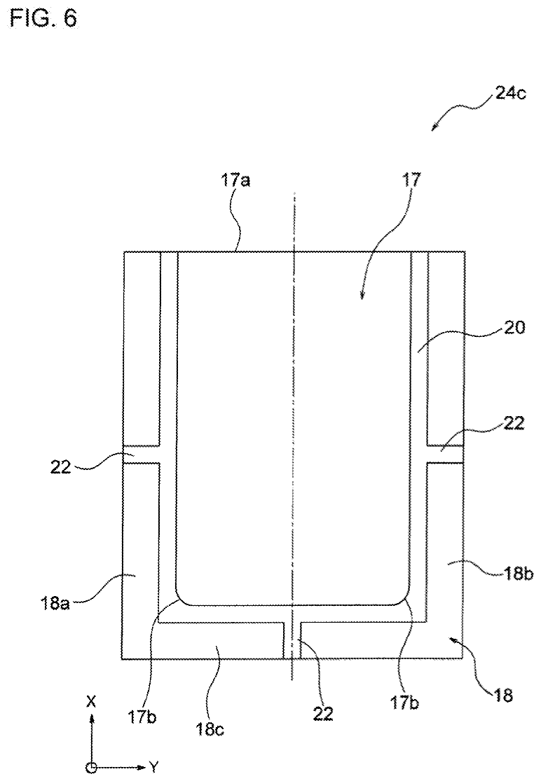

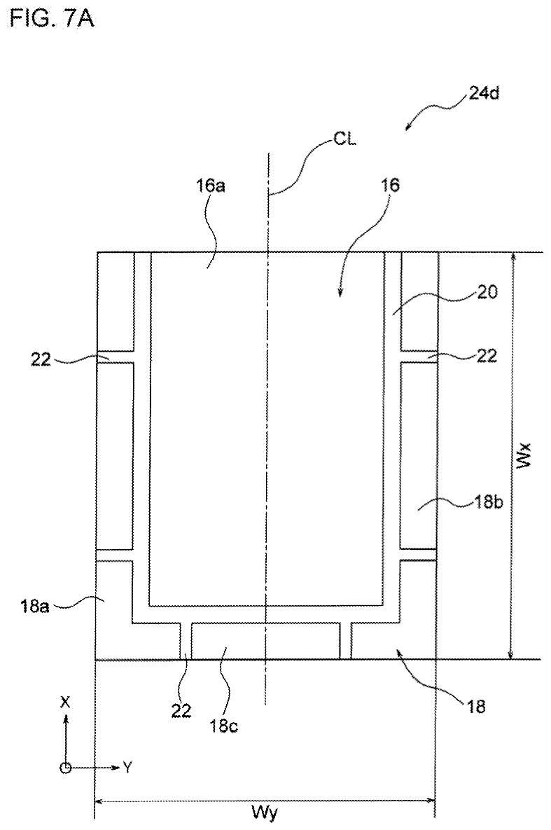

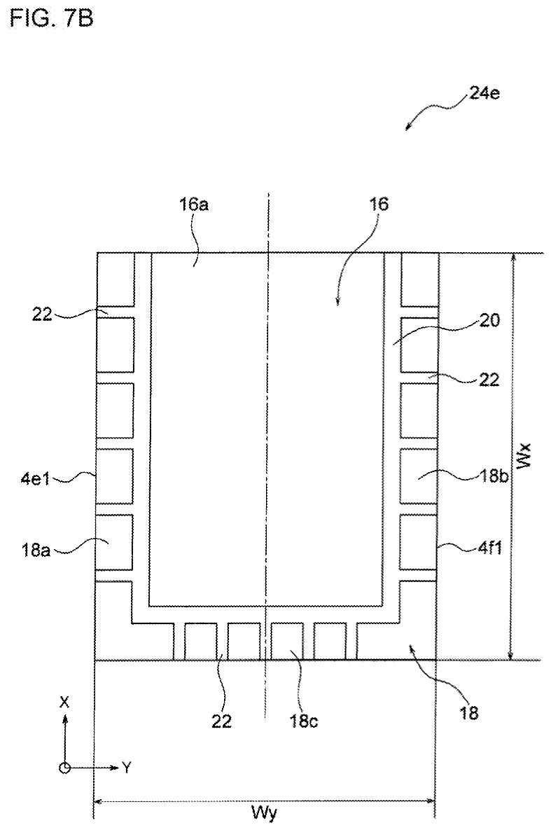

As shown in FIG. 2 and FIG. 3, the laminated body 4 has an internal structure in which piezoelectric layers 10 and internal electrode layers 16 are alternately laminated in the lamination direction (Z-axis direction). The internal electrode layers 16 are laminated so that leading portions 16a are alternately exposed to the lateral surfaces 4c and 4d of the laminated body 4. At the leading portions 16a, the internal electrode layers 16 are electrically connected with the first external electrode 6 or the second external electrode 8.

In the present embodiment, the piezoelectric layers 10 at a central part of the laminated body 4 have piezoelectric active parts 12 sandwiched by the internal electrode layers 16. That is, the piezoelectric active parts 12 are a region surrounded by the dotted line shown in FIG. 2 and FIG. 3. In this region, a mechanical displacement is caused by voltage application via the first external electrode 6 and the second external electrode 8 having different polarities.

The internal electrode layers 16 are composed of any conductive material, such as a noble metal (e.g., Ag, Pd, Au, Pt), an alloy of these metals (e.g., Ag—Pd), a base metal (e.g., Cu, Ni), and an alloy of these metals. The first external electrode 6 and the second external electrode 8 are also composed of any conductive material, such as a material similar to the conductive material constituting the internal electrodes. Incidentally, a plating layer or a sputtered layer of the above-mentioned various metals may be formed on the exteriors of the first external electrode 6 and the second external electrode 8.

The piezoelectric layers 10 are made of any material that exhibits piezoelectric effect or inverse piezoelectric effect, such as PbZrₓTi₁₋ₓO₃ (PTZ), BaTiO₃ (BT), BiNaTiO₃ (BNT), BiFeO₃ (BFO), (Bi₂O₂)²⁺(Aₘ₋₁BₘO₃ₘ₊₁)²⁻ (BLSF), and (K,Na)NbO₃ (KNN). For improvement in characteristics, the piezoelectric layers 10 may contain a sub-component. The amount of the sub-component is determined based on desired characteristics.

Incidentally, the piezoelectric layers 10 have any thickness, but preferably have a thickness of about 0.5 to 100 μm in the present embodiment. Likewise, the internal electrode layers 16 have any thickness, but preferably have a thickness of about 0.5 to 2.0 μm. As shown in FIG. 2 and FIG. 3, the piezoelectric layers 10 are arranged on the front surface 4a and the back surface 4b of the laminated body 4.

FIG. 4A is a schematic plane view of a first electrode pattern 24a contained in the laminated body 4. The piezoelectric layers 10 are located along a plane including the X-axis and the Y-axis at the lower side of the Z-axis direction shown in FIG. 4A. The piezoelectric layer 10 has sides 4c1 to 4f1 corresponding to the lateral surfaces 4c to 4f of the laminated body 4 (see FIG. 1). Then, the internal electrode layer 16 and the first electrode pattern 24a made from a dummy electrode layer 18 are laminated on the surface of the piezoelectric layers 10.

In the first electrode pattern 24a shown in FIG. 4A, the internal electrode layer 16 has the leading portion 16a exposed to the side 4d1. The dummy electrode layer 18 is formed to surround the internal electrode layer 16 excluding the leading portion 16a via a gap 20. Thus, the internal electrode layer 16 and the dummy electrode layer 18 are insulated electrically.

In the present embodiment, the outer circumference of the dummy electrode layer 18 is exposed to the lateral surfaces 4c to 4f of the laminated body 4 and has a first lateral pattern 18a along the side 4e1, a second lateral pattern 18b along the side 4f1, and a joint pattern 18c along the side 4c1. The joint pattern 18c is located opposite to the leading portion 16a and joints the two lateral patterns 18a and 18b.

The dummy electrode layer 18 is made of any material that exhibits a thermal shrinkage behavior similar to that of the internal electrode layer 16, but is preferably made of the same material as the conductive material constituting the internal electrode layer 16. When the internal electrode layer 16 and the dummy electrode layer 18 are made of the same material, the internal electrode layer 16 and the dummy electrode layer 18 can be formed at the same time in manufacturing the laminated body 4 by printing method or so, which is an easy manufacture. The internal electrode layer 16 and the dummy electrode layer 18 may be, however, made of different compositions or materials.

The width W1 of the gap 20 is determined so that the internal electrode layer 16 and the dummy electrode layer 18 are not contacted with each other and is preferably 0.03 to 0.6 mm (more preferably, 0.1 to 0.5 mm) in the present embodiment. In this range, the insulating distance between the internal electrode layer 16 and the dummy electrode layer 18 is sufficiently secured, and the function of the dummy electrode layer 18 is not impaired.

As shown in FIG. 4A, one slit 22 is formed in each central part of the patterns 18a to 18c of the dummy electrode layer 18. Each of the slits 22 penetrates the outer circumstance and the inner circumstance of the dummy electrode layer 18 and is formed to divide the dummy electrode layer 18 in the longitudinal direction.

Preferably, the slits 22 have a width W2 of 0.03 to 0.6 mm (more preferably, 0.1 to 0.5 mm). In this range, the slits 22 are easily formed, and the function of the dummy electrode layer 18 can sufficiently be secured.

FIG. 5 is an exploded perspective view of the multilayer piezoelectric element 2 according to the present embodiment. When the piezoelectric layers 10 are laminated by three or more layers as shown in FIG. 5, the first electrode patterns 24a and the second electrode patterns 24b need to be laminated alternately. FIG. 4B shows a schematic plane view of the second electrode pattern 24b.

The second electrode pattern 24b has a form where the first electrode pattern 24a is rotated by 180 degrees around the Z-axis. That is, in the second electrode pattern 24b, the leading portion 16a of the internal electrode layer 16 is exposed to the side 4c1, and the joint pattern 18c of the dummy electrode layer 18 is exposed to the side 4d1. Except for these configurations, the second electrode pattern 24b is the same as the first electrode pattern 24a.

When a plurality of piezoelectric layers 10 and electrode patterns 24a and 24b is laminated as shown in FIG. 5, the displacement amount, the driving force, and the like can be increased compared to those of non-multilayer piezoelectric elements. In the present embodiment, the lamination number of piezoelectric layers 10 is two or more and has no upper limit, but is preferably about 3 to 20. The lamination number of piezoelectric layers 10 is appropriately determined based on the purpose of the multilayer piezoelectric element 2.

The multilayer piezoelectric element 2 according to the present embodiment is manufactured by any method and is, for example, manufactured by the following method.

First of all, a manufacturing step of the laminated body 4 is explained. In the manufacturing step of the laminated body 4, prepared are ceramic green sheets that will be the piezoelectric layer 10 after firing and a conductive paste that will be the internal electrode layer 16 and the dummy electrode layer 18 after firing.

For example, the ceramic green sheets are manufactured by the following manner. First of all, a raw material of a material constituting the piezoelectric layer 10 is mixed uniformly by wet mixing or so and is dried. Then, the raw material is calcined with appropriately determined conditions, and this calcined powder is pulverized in wet manner. The pulverized calcined powder is added with a binder and turned into a slurry. Then, the slurry is turned into a sheet by doctor blade method, screen printing method, or the like and is thereafter dried to obtain a ceramic green sheet. Incidentally, the raw material of the material constituting the piezoelectric layer 10 may contain inevitable impurities.

Next, a paste for electrodes containing a conductive material is applied onto the ceramic green sheet by printing method or so. This obtains green sheets where an internal electrode paste film and a dummy electrode paste film are formed in a predetermined pattern.

Next, the prepared green sheets are laminated in a predetermined order. That is, the green sheets on which the first electrode pattern 24a is printed and the green sheets on which the second electrode pattern 24b is printed are laminated alternately. In the portion constituting the front surface 4a of the laminated body after firing, only the ceramic green sheets are laminated.

Moreover, the laminated green sheets are pressurized for pressure bonding after the lamination and are fired to obtain the laminated body 4 after being subjected to necessary steps (e.g., drying step, debindering step). When the internal electrode layers are composed of a noble metal (e.g., Ag—Pd alloy), the firing is preferably carried out at a furnace temperature of 800 to 1200° C. and atmospheric pressure. When the internal electrode layers are composed of a base metal (e.g., Cu, Ni), the firing is preferably carried out at a furnace temperature of 800 to 1200° C. and an oxygen partial pressure of 1×10⁻⁷ to 1×10⁻⁹ MPa. When the laminated body is sintered in the firing step, the piezoelectric layer and the electrode layers (the internal electrode layer and the dummy electrode layer) are accompanied by volume shrinkage.

External electrodes are formed on the laminated body 4 obtained through the above steps. The external electrodes are formed by sputtering, vapor deposition, plating, dip coating, or the like. The first external electrode 6 is formed on the front surface 4a and the lateral surface 4d of the laminated body 4, and the second external electrode 8 is formed on the back surface 4b and the lateral surface 4c of the laminated body 4. Incidentally, an insulation layer may be formed by applying an insulating resin onto the lateral surfaces 4e and 4f of the laminated body 4 (the external electrodes 6 and 8 are not formed).

After the external electrodes are formed, a polarization treatment is carried out for allowing the piezoelectric layers 10 to have piezoelectric activity. The polarization treatment is carried out by applying a DC electric field of 1-10 kV/mm to the first and second external electrodes 6 and 8 in an insulating oil of about 80 to 120 degrees. Incidentally, the DC electric field to be applied depend upon the material constituting the piezoelectric layer 10. Through such a process, the multilayer piezoelectric element 2 shown in FIG. 1 is obtained.

In the above, the procedure for obtaining one multilayer piezoelectric element is shown, but actually used are green sheets on which multiple electrode patterns 24 are formed on one sheet. An aggregate laminate formed using such sheets is appropriately cut before or after firing and thereby finally has a shape of the element as shown in FIG. 1.

In the present embodiment, even when the piezoelectric layers 10 are thin, even when the piezoelectric layers 10 have a large lamination number, even when the laminated body 4 has a large lamination area, or the like, the formation of the slits 22 on the dummy electrode layer 18 makes it possible to further effectively prevent deformation of the laminated body 4 at the time of manufacture and to dramatically improve flatness of the laminated body 4.

The following reason is conceivable for appearance of deformation prevention effect by the slits 22. In the above-mentioned firing step, volume shrinkage is generated in the piezoelectric layers 10 and the electrode patterns 24 of the laminated body 4 of the multilayer piezoelectric element 2. At this time, the heat shrinkage behaviors are different from each other between the piezoelectric layers 10 and the electrode patterns 24.

In general, the shrinkage factor of the electrode patterns 24 is larger than that of the piezoelectric layers 10. Thus, shrinkage stress occurs near the electrode patterns 24, and tensile stress occurs near the piezoelectric layers 10. The stress generated inside the laminated body 4 is considered to deform the laminated body 4. In the present embodiment, the slits 22 are formed on the dummy electrode layer 18, and the stress can be released by the slits 22. Thus, the multilayer piezoelectric element 2 according to the present embodiment is hard to be affected by thermal shrinkage in the sintering step and can remarkably prevent deformation of the laminated body 4.

In the present embodiment, the piezoelectric layers 10 have any thickness and any lamination number, and the laminated body 4 has any size, but the following case is further effectively applicable. As described above, the laminated body 4 is easily deformable when the piezoelectric layers 10 are thin, but the laminated body 4 with a good flatness can be obtained even if the piezoelectric layers 10 have a thickness of 1 to 50 μm. Likewise, the laminated body 4 with a good flatness can also be obtained even if the piezoelectric layers 10 have a large lamination number of 2 to 20. The laminated body 4 with a good flatness can also be obtained even if the piezoelectric layers 10 have a large area of 100 (Wx) mm×100 (Wy) mm or more.

In the present embodiment, a remarkable deformation prevention effect can be obtained by the slits 22, and the internal electrode layers 16 can thereby have a high area ratio.

Specifically, a ratio of an area (Ae) of the internal electrode layer 16 to an area (Ap) of the piezoelectric layer 10 on a plane including the X-axis and the Y-axis can be 0.95≤Ae/Ap≤0.99. The area (Ae) of the internal electrode layer 16 corresponds to a volume of the piezoelectric active part 12, which demonstrates piezoelectric characteristics. Thus, when the internal electrode layer 16 has a high area ratio, the relative dielectric constant ε and the piezoelectric constant d33 (or d31) of the piezoelectric element can be improved.

When no slits 22 are formed, it is practically difficult for the internal electrode layer 16 to have an area ratio in the above range. That is, when the internal electrode layer 16 has an area ratio (Ae/Ap) in the above range, an effect that cannot be achieved by conventional arts is exhibited.

In the present embodiment, as shown in FIG. 4A, three slits 22 are formed on the dummy electrode layer 18. To obtain the effects of the present invention, however, at least one slit 22 is formed. If the slits 22 are devised in terms of formation position, form, etc., the above-mentioned effects of the present invention can further be enhanced.

Specifically, the slits 22 are preferably formed at the following positions.

As shown in FIG. 4A, the first lateral pattern 18a and the second lateral pattern 18b of the dummy electrode layer 18 have ends 18d and 18e exposed to the side 4d1 similarly to the leading portions 16a. Preferably, the slits 22 are formed at a position away from the ends 18d and 18e by a predetermined distance “d” or larger. Incidentally, the predetermined distance “d” is preferably ⅛ or larger (more preferably, ⅙ or larger) of a width Wx of the dummy electrode layer 18 in the X-axis direction. When the slits are formed at such a position, the stress generated in the dummy electrode layer 18 can more effectively be reduced, and the improvement effect on flatness is improved.

Incidentally, if at least one or more slits 22 are formed at a position away from the ends 18d and 18e by a predetermined distance or larger, the slits 22 may be formed at a position away from the ends 18d and 18e by the above-mentioned predetermined distance or smaller.

Preferably, as shown in FIG. 4A, each of the slits 22 are formed at a central part of the respective patterns 18a to 18c of the dummy electrode layer 18.

In the firing, the shrinkage stress generated in the dummy electrode layer 18 is easy to concentrate on the central part of the respective patterns 18a to 18c. Thus, the dummy electrode layer is formed continuously, and if there are no slits, swell and dent are easily generated at a central position of the laminated body 4 in the X-axis direction or the Y-axis direction. When each of the slits 22 is formed at a central part of the respective patterns, on which the stress is easy to concentrate, it is possible to further effectively release the stress and to enhance the deformation prevention effect.

Preferably, the slits penetrate the outer circumference and the inner circumference of the dummy electrode layer 18 so as to divide it in the longitudinal direction (see FIG. 4A). When the slits 22 are formed in such a manner, the first external electrode 6 and the second external electrode 8 are not conducted with each other via the dummy electrode layer 18, and short circuit can be prevented. Thus, the lateral electrodes can be formed on the entire lateral surfaces 4c and 4d of the laminated body 4.

However, the slits 22 may not necessarily divide the dummy electrode layer 18 and may have a cut shape that does not divide the outer circumference and the inner circumference of the dummy electrode layer 18. The slits 22 may be formed diagonally to the X-axis or the Y-axis.

Preferably, when the slits 22 have a cut shape, the lateral parts 6a and 8a of the external electrodes 6 and 8 shown in FIG. 1 are formed to have a width in the Y-axis direction that is smaller than a width W3 of the internal electrode layer 16 (see FIG. 4A). This is because if the lateral parts 6a and 8a have a width that is larger than a width W3, the first external electrode 6 and the second external electrode 8 are connected with each other via the dummy electrode layer 18, and short circuit is generated.

### Second Embodiment

Hereinafter, Second Embodiment of the present invention is explained based on FIG. 6. Incidentally, the common configurations between First Embodiment and Second Embodiment are not explained.

FIG. 6 is a schematic plane view illustrating an electrode pattern 24c contained in a multilayer piezoelectric element 2a according to Second Embodiment. Except that an internal electrode layer 17 is configured differently as shown in FIG. 6, the multilayer piezoelectric element 2a according to the present embodiment is similar to the multilayer piezoelectric element 2 according to First Embodiment and demonstrates effects similar to those of the multilayer piezoelectric element 2 according to First Embodiment.

In the internal electrode layer 17 contained in the electrode pattern 24c, as shown in FIG. 6, corners 17b located opposite to a leading portion 17a are rounded. Preferably, the rounded corners 17b have a curvature radius of 0.1 mm or larger.

An electric field is easy to concentrate on the corners 17b of the internal electrode layer 17 at the time of application of DC electric field during polarization. In particular, when the piezoelectric layers 10 are made of a lead-free based material, a voltage for polarization is higher compared to when the piezoelectric layers 10 are made of PZT, and short circuit is easily generated at corners of an internal electrode layer during polarization. In the present embodiment, since the corners 17b of the internal electrode layer 17 are rounded, an electric field is prevented from concentrating on the corners 17b, and short-circuit failure can effectively be prevented from occurring during polarization.

### Third Embodiment

Hereinafter, Third Embodiment of the present invention is explained based on FIG. 7A. Incidentally, the common configurations between First Embodiment and Third Embodiment are not explained.

FIG. 7A is a schematic plane view illustrating an electrode pattern 24d contained in a multilayer piezoelectric element 2b according to Third Embodiment. Except that a different number of slits 22 is formed at different positions as shown in FIG. 7A, the multilayer piezoelectric element 2b according to the present embodiment is similar to the multilayer piezoelectric element 2 according to First Embodiment and demonstrates effects similar to those of the multilayer piezoelectric element 2 according to First Embodiment.

In the present embodiment, as shown in FIG. 7A, two slits 22 are formed symmetrically to the center of the respective patterns 18a to 18c of the dummy electrode layer 18. Since the slits 22 are formed at such positions, the dummy electrode layer 18 has a line-symmetrical pattern to a center line CL equally dividing the dummy electrode layer 18.

Since the slits 22 are formed regularly, it is possible to equally divide a stress generated in the dummy electrode layer 18 in the firing step and to prevent a partial concentration of the stress. Thus, the multilayer piezoelectric element 2b according to the present embodiment can further enhance the deformation prevention effect of the laminated body 4. Incidentally, although First Embodiment does not explain, the slits 22 are also formed symmetrically to the center line CL in the electrode patterns shown in FIG. 4A and FIG. 4B and in FIG. 7B mentioned below.

### Fourth Embodiment

Hereinafter, Fourth Embodiment of the present invention is explained based on FIG. 7B. Incidentally, the common configurations between First Embodiment and Fourth Embodiment are not explained.

FIG. 7B is a schematic plane view illustrating an electrode pattern 24e contained in a multilayer piezoelectric element 2c according to Fourth Embodiment. Except that a different number of slits 22 is formed at different positions as shown in FIG. 7B, the multilayer piezoelectric element 2c according to the present embodiment is similar to the multilayer piezoelectric element 2 according to First Embodiment and demonstrates effects similar to those of the multilayer piezoelectric element 2 according to First Embodiment.

In each of the patterns 18a to 18c of the dummy electrode layer 18, as shown in FIG. 7B, the slits 22 are formed at equal intervals to equally divide respective sides 4e1, 4f1, and 4c1 into six portions. As mentioned in the explanation of FIG. 7A, the slits of the electrode pattern 24e are formed line-symmetrically to the center line CL.

Like the electrode pattern 24e, the number of slits 22 is preferably larger within a predetermined range. The larger the number of slits 22 is within a predetermined range, the more effectively a stress generated in the dummy electrode layer 18 in the firing step can be dispersed, and the smaller the stress remaining in the laminated body 4 can become.

When the number of slits 22 is too large, however, the original function as the dummy electrode layer (deformation prevention) may be disturbed. For example, as shown in FIG. 7B, the number of slits formed in each of the patterns 18a to 18c of the dummy electrode layer 18 is preferably about 1 to 10. Since the dummy electrode layer 18 is formed from three patterns, when 1 to 10 slits 22 are formed in each of the patterns 18a to 18c, the total number of slits 22 is 3 to 30.

The present invention is not limited to the above-mentioned embodiments and can variously be changed within the scope of the present invention. For example, a laminated body may be formed by alternately laminating the electrode pattern 24d shown in FIG. 7A and the electrode pattern 24e shown in FIG. 7B. Any of the electrode patterns 24a to 24e shown in FIG. 4A to FIG. 7B and an electrode pattern having no dummy electrode layer 18 (not illustrated), an electrode pattern having no slits 22 (not illustrated), or the like may alternately be laminated.

The multilayer piezoelectric element according to the present invention can be utilized as a conversion element from electrical energy to mechanical energy. For example, the multilayer piezoelectric element according to the present invention is applicable to piezoelectric actuators, piezoelectric buzzers, piezoelectric sounders, ultrasonic motors, speakers, etc. and is particularly favorably utilized as piezoelectric actuators. Specifically, the piezoelectric actuators are utilized for haptic devices, lens driving, HDD head driving, inkjet printer head driving, fuel injection valve driving, etc.

### EXAMPLES

Hereinafter, the present invention is explained based on further detailed examples, but is not limited thereto.

### Experiment 1

First of all, predetermined amounts of chemically pure main-component raw material and sub-component raw material were weighed so that piezoelectric layers would be composed of PZT based ceramics, and the raw materials were mixed in wet manner in a ball mill. After the mixing, the mixture was calcined at 800° C. to 900° C. and pulverized in the ball mill. The calcined powder thus obtained was added with a binder and turned into a slurry. The slurry was turned into a sheet by screen printing method and thereafter dried to obtain ceramic green sheets.

Next, a conductive paste containing Ag—Pd alloy as main component was applied onto the ceramic green sheets by printing method. At this time, an electrode pattern was printed in a predetermined pattern so that a dummy electrode layer containing slits and an internal electrode layer would be formed after firing.

The green sheets thus obtained were laminated by nine or more layers in a predetermined order, and a pre-fired laminated body was obtained. Moreover, this laminated body was pressurized for pressure bonding, dried, debindered, and fired. The firing was carried out at 900° C. (furnace temperature) under atmospheric pressure.

In Experiment 1, an experiment was carried out by changing the number and formation position of slits, and samples of the laminated bodies shown in Examples 1 to 30 were obtained. Table 1 shows the number and formation position of slits in each Example. In each Example, 100 laminated bodies were prepared and subjected to the following evaluations.

Incidentally, the fired laminated bodies of Experiment 1 had a substantially rectangular parallelepiped shape of width (Wx) 30 mm×length (Wy) 30 mm×thickness 0.1 mm. The thickness of the piezoelectric layers was 10 μm on average. The thickness of the internal electrode layers was 1 μm on average. The width (W1) between the dummy electrode layers and the internal electrode layers was 0.3 mm on average. The width (W2) of the slits formed on the dummy electrode layers was 0.2 mm on average.

### Comparative Example 1

Except for forming no slits on the dummy electrode layers, samples of laminated bodies according to Comparative Example 1 were manufactured similarly to Examples 1 to 30.

### Measurement of Flatness

The flatness of the samples of the laminated bodies obtained in Comparative Example 1 and Examples 1 to 30 was measured using a CNC image measuring machine (NEXIV VMZ-R6555 manufactured by NIKON INSTECH CO., LTD.). The flatness was measured by making a least-square plane based on height data obtained by irradiating the laminated bodies with laser light and calculating a maximum height and a minimum height with the least-square plane as the reference plane. The flatness is represented by the maximum height—the minimum height. The smaller the flatness is, the less the laminated body is deformed. Incidentally, the measurement was carried out 900 times in each Example, and this average was obtained as a measurement result and is shown in Table 1. Incidentally, the target value of the flatness was 300 μm or smaller.

TABLE 1

| | | Number of | Formation Position of Slit(s) | | | | | | | |
|---|---|---|---|---|---|---|---|---|---|---|
| | Slit(s) of | Slits | Number of Each Pattern | | | Position of Each Pattern | | | | |
| Sample | Dummy | (Total | First Lateral Pattern | Second Lateral Pattern | Joint | Position | Position | Position | Position | Flatness |
| No. | Electrode | Number) | (Near Lateral Surface 4e) | (Near Lateral Surface 4f) | Pattern | A | B | C | D | μm |
| Comp. | no | 0 | — | — | — | — | — | — | — | 364 |
| Ex. 1 | | | | | | | | | | |
| Ex. 1 | yes | 1 | 1 | — | — | Y | — | — | — | 230 |
| Ex. 2 | yes | 1 | — | 1 | — | Y | — | — | — | 225 |
| Ex. 3 | yes | 1 | — | — | 1 | Y | — | — | — | 172 |
| Ex. 4 | yes | 1 | 1 | — | — | — | — | — | Y | 275 |
| Ex. 5 | yes | 1 | — | 1 | — | — | — | — | Y | 256 |
| Ex. 6 | yes | 1 | — | — | 1 | — | — | — | Y | 226 |
| Ex. 7 | yes | 2 | 2 | — | — | — | Y | — | — | 205 |
| Ex. 8 | yes | 2 | — | 2 | — | — | Y | — | — | 207 |
| Ex. 9 | yes | 2 | — | — | 2 | — | Y | Y | — | 172 |
| Ex. 10 | yes | 2 | 2 | — | — | — | — | — | Y | 244 |
| Ex. 11 | yes | 2 | — | 2 | — | — | — | — | Y | 242 |
| Ex. 12 | yes | 2 | — | — | 2 | — | — | — | Y | 219 |
| Ex. 13 | yes | 2 | 1 | — | 1 | Y | — | — | — | 155 |
| Ex. 14 | yes | 2 | 1 | 1 | — | Y | — | Y | — | 167 |
| Ex. 15 | yes | 2 | — | 1 | 1 | Y | — | — | — | 145 |
| Ex. 16 | yes | 2 | 1 | — | 1 | — | — | — | Y | 187 |
| Ex. 17 | yes | 2 | 1 | 1 | — | — | — | — | Y | 198 |
| Ex. 18 | yes | 2 | — | 1 | 1 | — | — | — | Y | 195 |
| Ex. 19 | yes | 4 | 2 | — | 2 | — | Y | — | — | 145 |
| Ex. 20 | yes | 4 | 2 | 2 | — | — | Y | Y | — | 159 |
| Ex. 21 | yes | 4 | — | 2 | 2 | — | Y | — | — | 167 |
| Ex. 22 | yes | 4 | 2 | — | 2 | — | — | — | Y | 197 |
| Ex. 23 | yes | 4 | 2 | 2 | — | — | — | — | Y | 203 |
| Ex. 24 | yes | 4 | — | 2 | 2 | — | — | — | Y | 206 |
| Ex. 25 | yes | 3 | 1 | 1 | 1 | Y | — | Y | — | 92 |
| Ex. 26 | yes | 3 | 1 | 1 | 1 | — | — | — | Y | 116 |
| Ex. 27 | yes | 6 | 2 | 2 | 2 | — | Y | Y | — | 74 |
| Ex. 28 | yes | 6 | 2 | 2 | 2 | — | — | — | Y | 103 |
| Ex. 29 | yes | 15 | 5 | 5 | 5 | Y | Y | Y | — | 54 |
| Ex. 30 | yes | 15 | 5 | 5 | 5 | — | — | — | Y | 83 |

### Evaluation

In terms of the formation position of the slits of Table 1, the position A is a central part of each of the patterns 18a to 18c of the dummy electrode layer, the position B is a symmetrical arrangement to the central part of each of the patterns 18a to 18c, the position C is a line-symmetrical arrangement to the center line CL, and the position D is a slit formation position excluding the positions A to C.

In Examples 1 to 30 of Table 1, when the slit formation position was any of the positions A to D, “Y” is given. Thus, Example 25 corresponds to the electrode pattern 24a shown in FIG. 4A, Example 27 corresponds to the electrode pattern 24d shown in FIG. 7A, and Example 29 corresponds to the electrode pattern 24e shown in FIG. 7B.

According to Table 1, when the slits were formed, the flatness was improved compared to Comparative Example 1. The larger the number of slits was, the smaller the flatness was, and the larger the deformation prevention effect of the laminated body became.

In Examples 1 to 6, the slit was formed at a position away from the end 18d (18e) of the lateral pattern 18a (18b) by a predetermined distance d or more. Here, the predetermined distance d of Examples was ⅛ of the width Wx of the electrode pattern 24 in the X-axis direction. In Examples 1 to 6, the target flatness was satisfied, and the deformation of the laminated bodies was effectively prevented by forming the slit at the above-mentioned position.

In Examples 1 to 6, the flatness was low by forming the slit on the joint pattern. This is probably because when one slit was formed, forming it on the joint pattern approximately divided the dummy electrode layer into two portions, and the deformation prevention effect was larger compared to when the slit was formed on the lateral pattern.

In Examples 1 to 6, the flatness of Examples 1 to 3 (the slit was formed at a central part of each pattern (position A)) was smaller than that of Examples 4 to 6. This tendency can also be found in Examples 13 to 15, 25, and 29, and a higher effect was obtained by forming the slits at a central part of each pattern.

In Examples 7 to 12, the flatness of Examples 7 to 9 was smaller than that of Examples 10 to 12. The deformation prevention effect of the laminated bodies was increased by forming the slits at the position B (symmetrical arrangement to the center of each pattern).

In Examples 7 to 12, any one of the patterns 18a to 18c of the dummy electrode layer was selected, and two slits were formed on the selected one pattern. In Examples 13 to 18, two patterns were selected from the patterns 18a to 18c, and the slits were formed on the selected two patterns. According to Table 1, compared to Examples 7 to 12, Examples 13 to 18 had a higher deformation prevention effect and a smaller flatness.

In Examples 19 to 24 and Examples 25 and 26, compared to Examples 19 to 24 (the total number of slits was larger), Examples 25 and 26 (the number of slits was smaller) had a smaller flatness. This shows that the deformation prevention effect of the laminated bodies did not merely depend upon the number of slits, but was also affected by the formation positions of the slits.

In Examples 7 to 25, the deformation of the laminated bodies was effectively prevented by forming the slits on the respective patterns 18a to 18c compared to forming the slits at a biased position.

In Examples 25, 27, and 29, when a plurality of slits was formed, the flatness was small by forming the slits at the position C (line-symmetrical arrangement to the center line CL).

In overall review of Examples 1 to 30 according to the present experiment, the deformation of the laminated bodies can more effectively be prevented by arranging multiple slits at the positions A to C with a certain regularity.

### Experiment 2

In Experiment 1, the laminated bodies were formed by alternately laminating the same electrode patterns while they were inverted. In Experiment 2, samples of laminated bodies of Examples 31 to 45 were manufactured by alternately laminating different electrode patterns (Examples 25 to 30) and were measured for flatness. The results are shown in Table 2. Incidentally, the other configurations of Examples 31 to 45 were common with those of Experiment 1.

TABLE 2

| Sample | Combination in Lamination | | Flatness |
|---|---|---|---|
| No. | Layer 1 | Layer 2 | μm |
| Ex. 31 | Ex. 25 | Ex. 26 | 101 |
| Ex. 32 | Ex. 25 | Ex. 27 | 79 |
| Ex. 33 | Ex. 25 | Ex. 28 | 92 |
| Ex. 34 | Ex. 25 | Ex. 29 | 63 |
| Ex. 35 | Ex. 25 | Ex. 30 | 80 |
| Ex. 36 | Ex. 26 | Ex. 27 | 99 |
| Ex. 37 | Ex. 26 | Ex. 28 | 118 |
| Ex. 38 | Ex. 26 | Ex. 29 | 69 |
| Ex. 39 | Ex. 26 | Ex. 30 | 99 |
| Ex. 40 | Ex. 27 | Ex. 28 | 95 |
| Ex. 41 | Ex. 27 | Ex. 29 | 53 |
| Ex. 42 | Ex. 27 | Ex. 30 | 85 |
| Ex. 43 | Ex. 28 | Ex. 29 | 71 |
| Ex. 44 | Ex. 28 | Ex. 30 | 100 |
| Ex. 45 | Ex. 29 | Ex. 30 | 92 |

Even in Examples 31 to 45 (different electrode patterns were laminated), the flatness was low, and the deformation prevention effect of the laminated bodies was not impaired. The flatness was the lowest in Example 41 (the electrode patterns of Examples 27 (FIG. 7A) and 29 (FIG. 7B) were laminated).

### Experiment 3

In Experiment 3, an experiment was carried out by changing the area ratio of the slit width and the internal electrode layer in the electrode pattern 24a of Example 25 shown in FIG. 4A, and samples of laminated bodies of Examples 46 to 49 were obtained. Incidentally, the other configurations of Examples 46 to 49 were common with those of Example 25. Table 3 shows the measurement results of the flatness of Examples 46 to 49.

TABLE 3

| | Slits of | Width of | Area Ratio of | |
|---|---|---|---|---|
| Sample | Dummy | Slits | Internal Electrode Layer | Flatness |
| No. | Electrode | mm | Ae/Ap | μm |
| Comp. Ex. 1 | no | — | 0.95 | 364 |
| Ex. 46 | yes | 0.03 | 0.95 | 96 |
| Ex. 47 | yes | 0.03 | 0.99 | 265 |
| Ex. 48 | yes | 0.6 | 0.95 | 84 |
| Ex. 49 | yes | 0.6 | 0.99 | 238 |

According to the results of Examples 46 to 49 shown in Table 3, the target flatness was obtained in a slit width of 0.03 mm to 0.6 mm. In Examples 46 and 48, the improvement effect on flatness tended to be higher when the slit width was 0.6 mm compared to when the slit width was 0.03 mm.

In Table 3, the area ratio of the internal electrode layer is a ratio (Ae/Ap) of an area (Ae) of the internal electrode layer to an area (Ap) of the piezoelectric layer. As shown in Table 3, Comparative Example 1 (no slits were formed) could not have a target flatness when the area ratio of the internal electrode layer was 0.95. Thus, when no slits were formed, the area ratio of the internal electrode layer needed to be smaller.

On the other hand, even though the area ratio of the internal electrode layer was large (0.99), Examples 46 to 49 had a target flatness of 300 μm or less in a slit width of 0.03 to 0.6 mm.

### Experiment 4

In Experiment 4, samples of laminated bodies were manufactured using the electrode pattern 24c shown in FIG. 6. That is, the corners of the internal electrode layer of Examples 50, 52, 54, and 56 according to Experiment 4 were rounded (curvature radius: 0.1 mm). The piezoelectric layers of Examples 1 to 49 were composed of lead-containing PZT based ceramic, but the samples of laminated bodies of Examples 53 to 56 were composed of lead-free based BFO-BT. Incidentally, the other configurations of Examples 50 to 56 were common with those of Example 25.

After the firing, a pair of external electrodes was formed on the samples of laminated bodies of Examples 50 and 51 and Example 25 according to Experiment 4. Then, a DC electric field was experimentally applied to the multilayer piezoelectric elements so as to confirm whether or not a short circuit was generated in each sample. Incidentally, this experiment was carried out for 100 samples in each Example so as to calculate a short-circuit rate. The results are shown in Table 4.

TABLE 4

| | | Roundness of | Piezoelectric | Application Voltage | | Short-Circuit |
|---|---|---|---|---|---|---|
| Sample | Slits of Dummy | Corners | Layer | in Test | Flatness | Rate |
| No. | Electrode | Yes or No | Material | kV/mm | μm | % |
| Ex. 25 | yes | no | PZT | 1.0 | 92 | 0 |
| Ex. 50 | yes | yes | PZT | 1.0 | 90 | 0 |
| Ex. 51 | yes | no | PZT | 2.0 | 93 | 0 |
| Ex. 52 | yes | yes | PZT | 2.0 | 93 | 0 |
| Ex. 53 | yes | no | BFO-BT | 3.0 | 101 | 0 |
| Ex. 54 | yes | yes | BFO-BT | 3.0 | 103 | 0 |
| Ex. 55 | yes | no | BFO-BT | 6.0 | 101 | 3 |
| Ex. 56 | yes | yes | BFO-BT | 6.0 | 104 | 0 |

According to Table 4, compared to Examples using lead based PZT, Examples 53 to 56 (the piezoelectric layers were composed of a lead-free based material) had a slightly higher flatness. This was caused by the difference in thermal shrinkage behavior of the piezoelectric layers, but a target flatness can be satisfied even though a lead-free based material was used. According to the present experiment, even though the material was changed, the present invention can have a deformation prevention effect by forming the slits.

When a lead-free based material is used, a voltage for polarization is several times higher compared to when a lead based material (e.g., PZT) is used. In Examples 53 to 56 (a lead-free based material was used), the test for short-circuit rate was thus carried out by applying a voltage that was several times higher compared to when a lead based material was used. In Example 55 (6.0 kV/mm, which was a test voltage being higher than a voltage for polarization, was applied), short circuit was consequently generated with a probability of about 3%. In Example 56 (the same voltage was applied), however, no short circuit was generated. This result indicates that the generation of short-circuit failures was effectively prevented by rounding the corners of the internal electrode layers, on which an electric field was easy to concentrate.

### DESCRIPTION OF THE REFERENCE NUMERICAL

2 . . . multilayer piezoelectric element
4 . . . laminated body
4a . . . front surface of laminated body
4b . . . back surface of laminated body
4c-4f . . . lateral surface of laminated body
6 . . . first external electrode
6a . . . first lateral part
6b . . . first surface part
8 . . . second external electrode
8a . . . second lateral part
8b . . . second surface part
10 . . . piezoelectric layer
12 . . . piezoelectric active part
16, 17 . . . internal electrode layer
16a, 17a . . . leading portion
17b . . . corner
18 . . . dummy electrode layer
18a, 18b . . . lateral pattern
18c . . . joint pattern
18d, 18e . . . end
20 . . . gap
22 . . . slit
24, 24a-24e . . . electrode pattern
4c1-4f1 . . . side

What is claimed is:

1. A multilayer piezoelectric element comprising:
a laminated body including:
a piezoelectric layer formed along a plane including a first axis and a second axis perpendicular to each other; and
an internal electrode layer and a dummy electrode layer laminated on the piezoelectric layer, and
a lateral electrode formed on a lateral surface of the laminated body perpendicular to the first axis,
wherein the internal electrode layer has a leading portion exposed to the lateral surface of the laminated body and is electrically connected with the lateral electrode via the leading portion,
wherein the dummy electrode layer is formed on the plane to surround the internal electrode layer excluding the leading portion with a gap therebetween, and
wherein a slit is formed at least at one or more positions of the dummy electrode layer.

2. The multilayer piezoelectric element according to claim 1, wherein the slit is formed on the dummy electrode layer at a position away from an end of the dummy electrode layer near the leading portion by a predetermined distance or more.

3. The multilayer piezoelectric element according to claim 2, wherein the predetermined distance is ⅛ or more of a first-axis width of the dummy electrode layer in the first axis.

4. The multilayer piezoelectric element according to claim 1, wherein
the dummy electrode layer includes two lateral patterns along the first axis and a joint pattern along the second axis,
the joint pattern is positioned opposite to the leading portion and joints the lateral patterns, and
the slit is formed at a center of the joint pattern or the lateral patterns of the dummy electrode layer.

5. The multilayer piezoelectric element according to claim 1, wherein two or more slits are formed line-symmetrically to a center line equally dividing the dummy electrode layer and being parallel to the first axis.

6. The multilayer piezoelectric element according to claim 1, wherein the slit has a width of 0.03 to 0.6 mm.

7. The multilayer piezoelectric element according to claim 1, wherein a ratio of an area (Ae) of the internal electrode layer to an area (Ap) of the piezoelectric layer in the plane is 0.95≤Ae/Ap≤0.99.

8. The multilayer piezoelectric element according to claim 1, wherein a corner of the internal electrode layer is rounded with a curvature radius of 0.1 mm or larger.

9. A piezoelectric actuator comprising the multilayer piezoelectric element according to claim 1.
